(19) United States
(12) Patent Application Publication
(10) Pub. No.: US 2024/0151478 A1
(43) Pub. Date: May 9, 2024

(54) LOOP HEAT PIPE, AND METHOD AND COMPONENT FOR REDUCING HEAT TRANSFER TEMPERATURE DIFFERENCE OF LOOP HEAT PIPE

(71) Applicant: ShengRongYuan(Suzhou) Technology Co., Ltd, Suzhou (CN)

(72) Inventors: Yongbin MU, Suzhou (CN); Xiuhong ZHAO, Suzhou (CN)

(73) Assignee: ShengRongYuan(Suzhou) Technology Co., Ltd, Suzhou (CN)

(21) Appl. No.: 18/279,868

(22) PCT Filed: Nov. 15, 2021
(86) PCT No.: PCT/CN2021/130715

§ 371 Date: Aug. 31, 2023

(30) Foreign Application Priority Data
Mar. 1, 2021 (CN) 2021102222228
Mar. 1, 2021 (CN) 2021204300532
Nov. 12, 2021 (CN) 2021113410663
Nov. 12, 2021 (CN) 2021227698099

(51) Int. Cl. F28D 15/04

(52) U.S. Cl. CPC F28D 15/043

(57) ABSTRACT

A method for reducing a heat transfer temperature difference of a loop heat pipe is provided. A second vapor chamber is provided between a first vapor chamber of an evaporator and a reservoir, a capillary structure is configured to separate the first vapor chamber from the second vapor chamber and to separate the second vapor chamber from the reservoir, the first vapor chamber communicates with a vapor line, and the second vapor chamber communicates with a liquid line through an auxiliary line. A component for reducing the heat transfer temperature difference of the loop heat pipe and a loop heat pipe including the same are also provided. The present disclosure can significantly reduce the heat leaked to the reservoir.

### FIELD OF TECHNOLOGY

The present disclosure relates to the technical field of heat dissipation devices, in particular, to a method for reducing the heat transfer temperature difference of a loop heat pipe, a component for reducing the heat transfer temperature difference of the loop heat pipe, and a loop heat pipe including the component for reducing the heat transfer temperature difference of the loop heat pipe.

### BACKGROUND

Heat pipes have dominated the field of electronic heat dissipation for a long time. However, in recent years, the performance of chips has been increasing, resulting in a continuous increase in heat generation. Existing heat pipes cannot meet the growing heat dissipation requirements of chips and therefore cannot keep up with the development of chips.

Loop heat pipes are advanced thermal control products developed to meet the complex and demanding thermal control requirements of spacecraft. A loop heat pipe includes five basic components: an evaporator (with capillary wick), a vapor line, a condenser, a liquid line, and a reservoir. These five components are connected in turn to form a closed loop, with working medium circulating inside. The working principle of the loop heat pipe is as follows: the evaporator contacts with a heat source, and the liquid-phase working medium vaporizes on the surface of the capillary wick inside the evaporator, so as to generate the driving force for circulating the working medium. The vaporized working medium enters the condenser along the vapor line and exothermically condenses into liquid-phase working medium in the condenser. The liquid-phase working medium then flows to the reservoir along the liquid line and soaks the capillary wick inside the evaporator, and the liquid-phase working medium is heated and evaporated again to enter the next cycle.

The loop heat pipe has all the advantages of the heat pipe while overcoming the inherent defects and deficiencies of the heat pipe. While the heat pipe enables the capillary wick to be sintered on the inner wall thereof, a reinforced capillary wick is provided in the evaporator of the loop heat pipe, which has stronger power. The vaporized working medium and the liquid-phase working medium are separated by arranging the vapor line and the liquid line, both of which are smooth pipes, so that the flow resistance of the working medium is smaller. Therefore, the loop heat pipe has a much stronger heat transfer capacity than the heat pipe, reaching more than 10 times that of the heat pipe. Applying the loop heat pipe for civilian use would be of great value.

However, as the pressure and temperature of the evaporator are higher than that of the reservoir during the normal operation of the loop heat pipe, heat load may be leaked from the evaporator to the reservoir, known as heat leakage. According to the working principle of the loop heat pipe, the heat leakage needs to be offset by increasing the subcooling degree of the liquid-phase working medium refluxed from the condenser to maintain the heat balance of the reservoir. The greater the heat leakage, the greater the required subcooling degree of the liquid-phase working medium refluxed from the condenser, resulting in a large heat transfer temperature difference between cold and hot ends of the loop heat pipe, which affects the heat transfer performance of the loop heat pipe. In particular, when the loop heat pipe is applied to civilian devices such as chips and CPUs for heat dissipation, the heat leakage problem is more prominent due to the large heat generation and high heat-flux density of the heat source, and the heat transfer temperature difference of the loop heat pipe is larger, as a result, the loop heat pipe cannot actually be applied.

Therefore, reducing the heat transfer temperature difference of the loop heat pipe becomes an urgent problem to be solved in order to make the loop heat pipe suitable for civilian devices.

### SUMMARY

The present disclosure provides a method and a component for reducing a heat transfer temperature difference of a loop heat pipe.

The present disclosure adopts the following technical solutions.

The present disclosure provides a method for reducing a heat transfer temperature difference of a loop heat pipe. The method includes: providing a second vapor chamber between a first vapor chamber of an evaporator and a reservoir, and separating the first vapor chamber from the second vapor chamber and separating the second vapor chamber from the reservoir by a capillary structure, the first vapor chamber communicates with a vapor line, and the second vapor chamber communicates with a liquid line through an auxiliary line.

Preferably, the method further includes: providing a working medium channel that communicates with the liquid line in a condenser, and the second vapor chamber and the working medium channel communicate with each other by the auxiliary line.

Preferably, the method further includes: providing an auxiliary condenser on the auxiliary line.

Preferably, the method further includes: setting the auxiliary line to pass through the condenser.

The present disclosure further provides a component for reducing the heat transfer temperature difference of a loop heat pipe, including an evaporator and a reservoir, wherein the evaporator includes a housing and a capillary structure, a first vapor chamber that communicates with a vapor line and a second vapor chamber that communicates with an auxiliary line are formed between the capillary structure and the housing, the auxiliary line is configured to communicate with a liquid line, the second vapor chamber is provided between the first vapor chamber and the reservoir, and the capillary structure is configured to separate the first vapor chamber from the second vapor chamber and to separate the second vapor chamber from the reservoir.

Preferably, the capillary structure is a one-piece structure.

Preferably, the capillary structure is a separable structure, the capillary structure includes a capillary wick and a capillary component, the first vapor chamber is formed between the capillary wick and the housing, the second vapor chamber is formed between the capillary component and the housing, and the capillary wick is in contact with or connected to the capillary component.

Preferably, the capillary structure is provided with a concave structure at a communication position between the evaporator and the auxiliary line, and the second vapor chamber is formed between the concave structure and the housing.

Preferably, a first channel and a plurality of second channels are provided in the capillary structure, the first channel is provided at the communication position between the evaporator and the auxiliary line, the plurality of second channels is distributed on the capillary structure, each of the plurality of the second channels is communicated with the first channel, and the first channel and the plurality of second channels together form the second vapor chamber with the housing.

Preferably, the housing is provided with a convex structure at the communication position between the evaporator and the auxiliary line, and the second vapor chamber is formed between the convex structure and the capillary structure.

Preferably, a wall of the housing is thinned to form a groove on a surface of the wall at the communication position between the evaporator and the auxiliary line, and the second vapor chamber is formed between the groove and the capillary structure.

Preferably, a porous structure is provided in the second vapor chamber.

The present disclosure also provides a loop heat pipe, including the component for reducing the heat transfer temperature difference of the loop heat pipe as described above.

Preferably, the loop heat pipe further includes the vapor line, a condenser, the liquid line and the auxiliary line, the vapor line connects the first vapor chamber with an inlet of the condenser, the liquid line connects the reservoir with an outlet of the condenser, and the second vapor chamber and the liquid line communicate with each other by the auxiliary line.

Preferably, a working medium channel that communicates with the liquid line is provided inside the condenser, and the second vapor chamber and the working medium channel communicate with each other by the auxiliary line.

Preferably, an auxiliary condenser is provided on the auxiliary line.

Preferably, the auxiliary line passes through the condenser.

Compared with the prior art, the present disclosure has significant progress:

A second vapor chamber and an auxiliary line are provided in the loop heat pipe according to the present disclosure, such that the heat leakage from the evaporator to the reservoir is isolated by the second vapor chamber. Specifically, part of the liquid-phase working medium is vaporized in the second vapor chamber due to the heat leakage, the vaporized working medium in the second vapor chamber flows to the auxiliary line, and finally flows back to the reservoir to complete a cycle. The vaporization of the working medium in the second vapor chamber absorbs most of the heat leakage from the evaporator to the reservoir, which can significantly reduce the heat leaked to the reservoir, thereby effectively reducing the heat transfer temperature difference of the loop heat pipe, and ensuring that the advantageous performance of the loop heat pipe can be well applied to civilian devices.

### BRIEF DESCRIPTION OF THE DRAWINGS

FIG. 1 is a cross-sectional view of a component for reducing a heat transfer temperature difference of a loop heat pipe according to the first example in Embodiment 2 of the present disclosure.

FIG. 2 is a cross-sectional view of a component for reducing a heat transfer temperature difference of a loop heat pipe according to the second example in Embodiment 2 of the present disclosure.

FIG. 3 is a cross-sectional view of a component for reducing a heat transfer temperature difference of a loop heat pipe according to the third example in Embodiment 2 of the present disclosure.

FIG. 4 is a schematic structural view of a component for reducing a heat transfer temperature difference of a loop heat pipe according to the fourth example in Embodiment 2 of the present disclosure.

FIG. 5 is a schematic structural diagram of the interior of FIG. 4.

FIG. 6 is a schematic structural view of a component for reducing a heat transfer temperature difference of a loop heat pipe according to the fifth example in Embodiment 2 of the present disclosure.

FIG. 7 is a cross-sectional view of FIG. 6.

FIG. 8 is a schematic structural view of a component for reducing a heat transfer temperature difference of a loop heat pipe according to the sixth example of the present disclosure.

FIG. 9 is a cross-sectional view of FIG. 8.

FIG. 10 is a schematic structural view of a loop heat pipe according to the first example in Embodiment 3 of the present disclosure.

FIG. 11 is a schematic structural view of a loop heat pipe according to the second example in Embodiment 3 of the present disclosure.

FIG. 12 is a schematic structural view of a loop heat pipe according to the third example in Embodiment 3 of the present disclosure.

FIG. 13 is a schematic structural view of a loop heat pipe according to the fourth example in Embodiment 3 of the present disclosure.

### REFERENCE NUMBERS

1 Evaporator
11 Housing
12 Capillary wick
13 First vapor chamber
2 Vapor line
3 Condenser
31 Working medium channel
4 Liquid line
5 Reservoir
6 Auxiliary line
7 Second vapor chamber
71 First channel
72 Second channel
8 Capillary component
9 Auxiliary condenser

### DETAILED DESCRIPTION

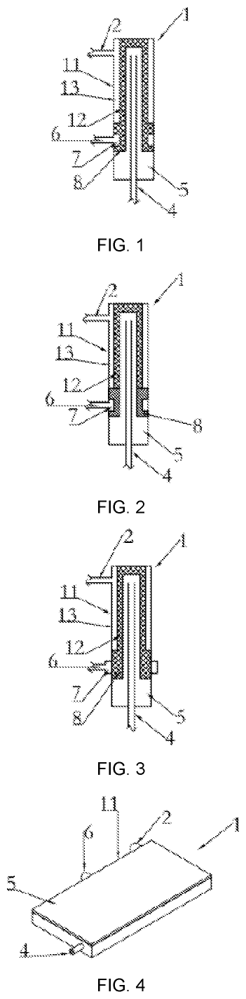

The specific embodiments of the present disclosure will be further described below in conjunction with the accompanying FIGS. 1-13. These embodiments are only intended to illustrate the scheme of the present disclosure, and should not be understood as limitative.

In the description of the present disclosure, it should be noted that, orientation or positional relationships indicated by terms “center”, “longitudinal”, “transverse”, “upper”, “lower”, “front”, “rear”, “left”, “right”, “vertical”, “horizontal”, “top”, “bottom”, “inner”, “outer”, etc. are based on the orientation or positional relationships shown in the accompanying drawings, and are only for the convenience of describing the present disclosure as well as simplifying the description, do not indicate or imply that the relevant devices or elements must have a particular orientation and be configured or operated in the particular orientation. Therefore, they should not be construed as limitative. In addition, the terms like “first” and “second” are used for indication purpose only, and are not to be construed as indicating or implying relative importance.

In the description of the present disclosure, it should be noted that, unless otherwise specified and limited, terms “installation”, “attachment” and “connection” should be understood in a broad sense, for example, it can be a fixed connection, a detachable connection or an integrated connection; it can be mechanically connected or electrically connected; it can be directly connected or indirectly connected through an intermedium, and it can also be an internal communication between two components. Those of ordinary skill in the art can understand the specific meanings of the above terms in the present disclosure, according to specific situations.

In addition, in the description of the present disclosure, unless otherwise specified, “a plurality of” means two or more.

The loop heat pipe includes an evaporator 1, a vapor line 2, a condenser 3, a liquid line 4, and a reservoir 5. The evaporator 1 includes a housing 11 and a capillary wick 12. A first vapor chamber 13 that communicates with the vapor line 2 is formed between the capillary wick 12 and the housing 11. The vapor line 2 connects the first vapor chamber 13 with an inlet of the condenser 3, and the liquid line 4 connects the reservoir 5 with an outlet of the condenser 3. The capillary wick 12 separates the reservoir 5 from the first vapor chamber 13 of the evaporator 1. The capillary wick 12 can be permeated with a liquid-phase working medium and can prevent the vaporized working medium from circulating between the reservoir 5 and the first vapor chamber 13. The working principle of the loop heat pipe is as follows: the evaporator 1 contacts with a heat source, and the liquid-phase working medium vaporizes on the surface of the capillary wick 12 inside the evaporator 1 to generate a driving force for circulating the working medium. The vaporized working medium flows from the first vapor chamber 13 to the vapor line 2, then passes through the vapor line 2 and enters the condenser 3, and the vaporized working medium exothermically condenses into the liquid-phase working medium in the condenser 3. The liquid-phase working medium then flows from the condenser 3 to the liquid line 4, then passes through the liquid line 4 and enters the reservoir 5. The liquid-phase working medium permeates and soaks the capillary wick 12 inside the evaporator 1, and the liquid-phase working medium is heated and evaporated again to enter the next cycle.

The heat transfer temperature difference of the loop heat pipe is caused by the heat load (heat leakage) leaked from the evaporator 1 to the reservoir 5. The greater the heat leakage, the greater the heat transfer temperature difference of the loop heat pipe. The heat conduction through the housing 11 and the capillary wick 12 between the evaporator 1 and the reservoir 5 is an important source of the heat leakage. Therefore, the reduction of the heat conduction can reduce the heat leakage leaked to the reservoir 5, thereby reducing the heat transfer temperature difference of the loop heat pipe, and ensuring that the advantageous performance of the loop heat pipe can be well applied to civilian devices. In light of this, the present disclosure provides a method for reducing the heat transfer temperature difference of the loop heat pipe, which reduces the heat transfer temperature difference of the loop heat pipe by reducing the heat leaked to the reservoir 5. The present disclosure also provides a component for reducing the heat transfer temperature difference of the loop heat pipe, which can realize the above-mentioned method for reducing the heat transfer temperature difference of the loop heat pipe. The present disclosure further provides a loop heat pipe, which includes the above-mentioned component for reducing the heat transfer temperature difference of the loop heat pipe.

### Embodiment I

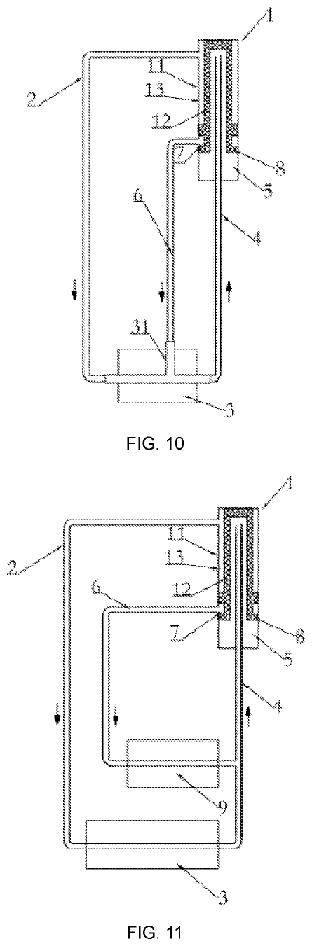

Refer to FIGS. 10 to 12, a method for reducing a heat transfer temperature difference of a loop heat pipe is provided according to Embodiment I of the present disclosure.

The method of Embodiment I is as follows: a second vapor chamber 7 is provided between the first vapor chamber 13 and the reservoir 5, a capillary structure separates the first vapor chamber 13 from the second vapor chamber 7 and separates the second vapor chamber 7 from the reservoir 5, the capillary structure can be permeated with the liquid-phase working medium and can prevent the vaporized working medium from circulating between the first vapor chamber 13 and the second vapor chamber 7, and between the second vapor chamber 7 and the reservoir 5. The first vapor chamber 13 communicates with the vapor line 2, and the second vapor chamber 7 communicates with the liquid line 4 through an auxiliary line 6. Thus, when the evaporator 1 is in contact with the heat source to absorb heat from the heat source, the working medium in the first vapor chamber 13 is vaporized, and the vaporized working medium passes through the vapor line 2 and enters the condenser 3, and exothermically condenses into the liquid-phase working medium in the condenser 3, then the condensed liquid-phase working medium passes through the liquid line 4 and flows back to the reservoir 5 and the evaporator 1, thus completing one cycle. At the same time, as the temperature and pressure in the evaporator 1 are higher than those of the working medium in the reservoir 5, the evaporator 1 begins to transfer heat to the reservoir 5. When the heat is transferred to the second vapor chamber 7, the liquid-phase working medium in the second vapor chamber 7 is heated and vaporized, this process absorbs most of the heat transferred from the evaporator 1 to the reservoir 5, thus significantly reducing the heat leaked to the reservoir 5. The working medium vaporized in the second vapor chamber 7 passes through the auxiliary line 6 and flows to the liquid line 4, then flows back to the reservoir 5 together with the condensed working medium that flows through the vapor line 2, thereby completing another cycle. These two cycles are performed side-by-side at the same time.

Therefore, in the method for reducing the heat transfer temperature difference of the loop heat pipe of Embodiment I, by adding the second vapor chamber 7 and the auxiliary line 6, the heat leakage from the evaporator 1 to the reservoir 5 is isolated by the second vapor chamber 7. Specifically, part of the liquid-phase working medium is vaporized in the second vapor chamber 7 due to the heat leakage, the vaporized working medium in the second vapor chamber 7 flows to the auxiliary line 6, then passes through the liquid line 4 and finally flows back to the reservoir 5 to complete a cycle. The vaporization of the working medium in the second vapor chamber 7 absorbs most of heat leakage from the evaporator 1 to the reservoir 5, which can significantly reduce the heat leaked to the reservoir 5, thereby effectively reducing the heat transfer temperature difference of the loop heat pipe, and ensuring that the advantageous performance of the loop heat pipe can be well applied to civilian devices.

In Embodiment I, the capillary structure may include a capillary wick 12 and a capillary component 8. The first vapor chamber 13 is formed between the capillary wick 12 and the housing 11, the second vapor chamber 7 is formed between the capillary component 8 and the housing 11, and the capillary component 8 separates the first vapor chamber 13 from the second vapor chamber 7 and separates the second vapor chamber 7 from the reservoir 5. The capillary component 8 can be permeated with the liquid-phase working medium and can prevent the vaporized working medium from circulating between the first vapor chamber 13 and the second vapor chamber 7, and between the second vapor chamber 7 and the reservoir 5. The capillary wick 12 and the capillary component 8 may form a one-piece structure, that is, the capillary component 8 is part of the capillary wick 12, and the formed capillary structure has a one-piece structure. The capillary wick 12 and the capillary component 8 may also be separate structures that are in contact or connected with each other, and the formed capillary structure has a separable structure.

Preferably, in Embodiment I, a porous structure (not shown in the figures) may be partially or completely filled in the second vapor chamber 7 to play a supporting role.

In Embodiment I, the communication method between the auxiliary line 6 and the liquid line 4 is not limited, and any one of the following three communication methods can be preferably adopted.

Refer to FIG. 10, in the first preferred communication method between the auxiliary line 6 and the liquid line 4, a working medium channel 31 that communicates with the liquid line 4 is provided inside the condenser 3, two ends of the auxiliary line 6 respectively communicate with the second vapor chamber 7 and the working medium channel 31, and the auxiliary line 6 communicates with the liquid line 4 through the working medium channel 31 and the outlet of the condenser 3, thus the second vapor chamber 7 can communicate with the liquid line 4 via the auxiliary line 6. Therefore, the vaporized working medium in the second vapor chamber 7 enters the auxiliary line 6, then passes through the auxiliary line 6 and the working medium channel 31, and flows to the condenser 3. The vaporized working medium exothermically condenses into the liquid-phase working medium in the condenser 3, and the liquid-phase working medium then passes through the liquid line 4 and flows back to the reservoir 5 together with the condensed working medium that flows through the vapor line 2.

Refer to FIG. 11, in the second preferred communication method between the auxiliary line 6 and the liquid line 4, an auxiliary condenser 9 is provided on the auxiliary line 6, and the two ends of the auxiliary line 6 communicate with the second vapor chamber 7 and the liquid line 4 respectively. Thus, the vaporized working medium in the second vapor chamber 7 flows through the auxiliary line 6, and enters the auxiliary condenser 9. The vaporized working medium condenses into the liquid-phase working medium in the auxiliary condenser 9, and the liquid-phase working medium then passes through the liquid line 4 and flows back to the reservoir 5.

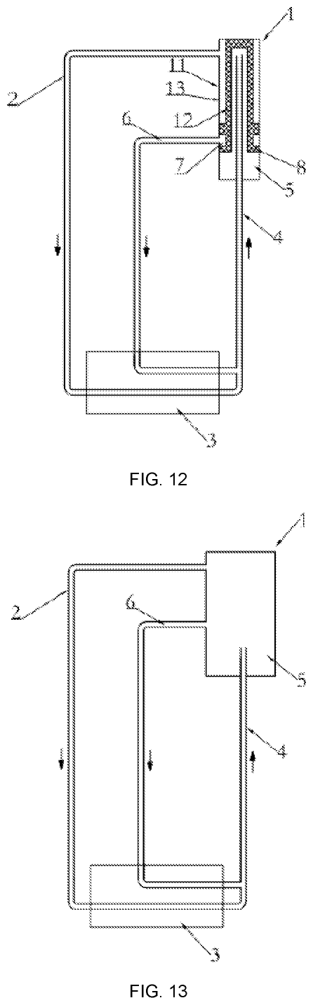

Refer to FIG. 12, in the third preferred communication method between the auxiliary line 6 and the liquid line 4, the auxiliary line 6 can pass through the condenser 3, the two ends of the auxiliary line 6 communicate with the second vapor chamber 7 and the liquid line 4 respectively, and part of the auxiliary line 6 passes through the condenser 3. Thus, the vaporized working medium in the second vapor chamber 7 flows through the auxiliary line 6, and enters the condenser 3. The vaporized working medium condenses into the liquid-phase working medium in the condenser 3, and the liquid-phase working medium then passes through the liquid line 4 and flows back to the reservoir 5.

According to the method for reducing the heat transfer temperature difference of the loop heat pipe of Embodiment I, the limitation of the principle of the loop heat pipe used in aerospace is broken, and the heat leakage can be reduced without limiting materials and working medium, so that more favorable materials, working medium and matched processes can be adopted to meet the requirements of civilian devices with high power and high heat-flux density. The heat transfer temperature difference generated by conventional loop heat pipes using the same working medium and an approximate capillary structure generally exceeds 35° C., while the heat transfer temperature difference generated by the loop heat pipe of Embodiment I can be reduced to 5-10° C. or less, therefore, the performance of the improved loop heat pipe can meet the requirements of civilian devices such as chips and power electronic devices.

### Embodiment II

Refer to FIGS. 1 to 9, a component for reducing a heat transfer temperature difference of a loop heat pipe is provided according to Embodiment II of the present disclosure. The component for reducing the heat transfer temperature difference of the loop heat pipe provided by Embodiment II can realize the method for reducing the heat transfer temperature difference of the loop heat pipe according to Embodiment I.

The component for reducing the heat transfer temperature difference of the loop heat pipe of Embodiment II includes an evaporator 1 and a reservoir 5. The evaporator 1 includes a housing 11 and a capillary structure. A first vapor chamber 13 that communicates with a vapor line 2 and a second vapor chamber 7 that communicates with an auxiliary line 6 are formed between the capillary structure and the housing 11. The auxiliary line 6 is configured to communicate with a liquid line 4, and the liquid line 4 communicates with the reservoir 5. The second vapor chamber 7 is provided between the first vapor chamber 13 and the reservoir 5, and the capillary structure separates the first vapor chamber 13 from the second vapor chamber 7 and separates the second vapor chamber 7 from the reservoir 5. The capillary structure can be permeated with a liquid-phase working medium and can prevent the vaporized working medium from circulating between the first vapor chamber 13 and the second vapor chamber 7, and between the second vapor chamber 7 and the reservoir 5.

In the component for reducing the heat transfer temperature difference of the loop heat pipe of Embodiment II, by adding the second vapor chamber 7 and the auxiliary line 6, the heat leakage from the evaporator 1 to the reservoir 5 is isolated by the second vapor chamber 7. When the heat transferred from the evaporator 1 is thermally transferred to the second vapor chamber 7 before going to the reservoir 5, the working medium is vaporized in the second vapor chamber 7, the vaporized working medium in the second vapor chamber 7 flows to the auxiliary line 6, and finally passes through the liquid line 4 and flows back to the reservoir 5 to complete a cycle. The vaporization of the working medium in the second vapor chamber 7 absorbs most of heat leakage from the evaporator 1 to the reservoir 5, which can significantly reduce the heat leaked to the reservoir 5, thereby effectively reducing the heat transfer temperature difference of the loop heat pipe, and ensuring that the advantageous performance of the loop heat pipe can be well applied to civilian devices.

In Embodiment II, the capillary structure may include a capillary wick 12 and a capillary component 8. The first vapor chamber 13 is formed between the capillary wick 12 and the housing 11, the second vapor chamber 7 is formed between the capillary component 8 and the housing 11, and the capillary component 8 separates the first vapor chamber 13 from the second vapor chamber 7 and separates the second vapor chamber 7 from the reservoir 5. Thus, the capillary component 8 is close to the reservoir 5. The capillary component 8 can be permeated with the liquid-phase working medium and can prevent the vaporized working medium from circulating between the first vapor chamber 13 and the second vapor chamber 7, and between the second vapor chamber 7 and the reservoir 5.

Refer to FIGS. 1, 3, 7 and 9, the capillary wick 12 and the capillary component 8 may form a one-piece structure, that is, the capillary component 8 is part of the capillary wick 12, and the formed capillary structure is a one-piece structure.

Refer to FIG. 2, the capillary wick 12 and the capillary component 8 may be separate structures that are in contact or connected with each other, and the formed capillary structure is a separable structure.

In Embodiment II, preferably, a porous structure (not shown in the figures) may be partially or completely filled in the second vapor chamber 7 to play a supporting role.

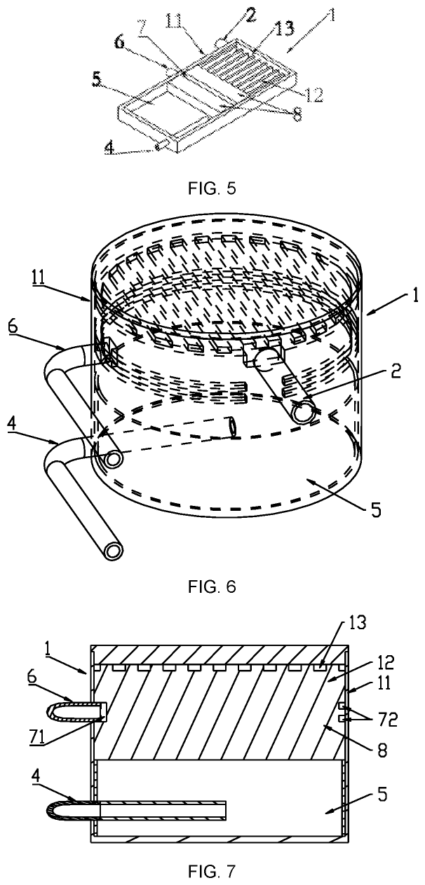

In embodiment II, refer to FIGS. 1, 2, 3, and 6 to 9, the evaporator 1 may be a cylindrical structure. Refer to FIGS. 4 and 5, the evaporator 1 may also be a flat structure.

In Embodiment II, the formation method of the second vapor chamber 7 is not limited, and any one of the following four formation methods can be preferably adopted.

Refer to FIGS. 1, 2 and 5, in the first preferred formation method of the second vapor chamber 7, the capillary structure is provided with a concave structure at a position where the evaporator 1 is connected with the auxiliary line 6, the concave structure is arranged on the capillary component 8 of the capillary structure close to the reservoir 5, and the second vapor chamber 7 is formed between the concave structure and the housing 11.

Refer to FIG. 3, in the second preferred formation method of the second vapor chamber 7, the housing 11 is provided with a convex structure at the communication position between the evaporator 1 and the auxiliary line 6 of the housing 11, and the second vapor chamber 7 is formed between the convex structure and the capillary component 8 of the capillary structure close to the reservoir 5.

Refer to FIGS. 6, 7 and 9, in the third preferred formation method of the second vapor chamber 7, a first channel 71 and a plurality of second channels 72 are provided on the capillary structure, the first channel 71 is provided at the communication position between the evaporator 1 and the auxiliary line 6, the plurality of second channels 72 is distributed on the capillary structure, each of the second channels communicates with the first channel 71, and the first channel 71 and the plurality of second channels 72 together form the second vapor chamber 7 with the housing 11.

In the fourth preferred formation method of the second vapor chamber 7, a wall of the housing 11 is thinned to form a groove on a surface of the wall at the communication position between the evaporator 1 and the auxiliary line 6, and the second vapor chamber 7 is formed between the groove and the capillary component 8 of the capillary structure close to the reservoir 5.

Six specific examples of the component for reducing the heat transfer temperature difference of the loop heat pipe according to Embodiment II are provided below.

FIG. 1 shows the first example of the component for reducing the heat transfer temperature difference of the loop heat pipe of Embodiment II. In the first example, the evaporator 1 is a cylindrical structure. The evaporator 1 includes a housing 11 and a capillary structure. The capillary structure includes a capillary wick 12 and a capillary component 8. A first vapor chamber 13 that communicates with a vapor line 2 is formed between the capillary wick 12 and the housing 11, a second vapor chamber 7 that communicates with an auxiliary line 6 is formed between the capillary component 8 and the housing 11, and the auxiliary line 6 is configured to communicate with a liquid line 4. The capillary component 8 separates the first vapor chamber 13 from the second vapor chamber 7 and separates the second vapor chamber 7 from a reservoir 5. The capillary component 8 is part of the capillary wick 12, the capillary structure thus has a one-piece structure. The capillary component 8 of the capillary structure close to the reservoir 5 is provided with a concave structure at a communication position between the evaporator 1 and the auxiliary line 6, the concave structure forms an annular groove around the capillary component 8, and the second vapor chamber 7 is formed between the annular groove and the housing 11. A porous structure (not shown in the figures) may be partially or completely filled in the second vapor chamber 7 to play a supporting role.

FIG. 2 shows the second example of the component for reducing the heat transfer temperature difference of the loop heat pipe of Embodiment II. The component of the second example is similar to that of the first example, so the similarities will not be repeated. The differences are that, in the component of the second example, the capillary wick 12 and the capillary component 8 are separate structures that are in contact or connected with each other, and the capillary structure thus has a separable structure.

FIG. 3 shows the third example of the component for reducing the heat transfer temperature difference of the loop heat pipe of Embodiment II. The component of the third example is similar to that of the first example, so the similarities will not be repeated. The differences are that, in the component of the third example, the housing 11 is provided with a convex structure at the communication position between the evaporator 1 and the auxiliary line 6, the convex structure forms an annular protruding shell on the housing 11 around the housing 11, and the second vapor chamber 7 is formed between the annular protruding shell and the capillary component 8 of the capillary structure close to the reservoir 5.

FIGS. 4 and 5 show the fourth example of the component for reducing the heat transfer temperature difference of the loop heat pipe of Embodiment II. The component of the fourth example is similar to that of the first example, so the similarities will not be repeated. The differences are that, in the component of the fourth example, the evaporator 1 is a flat structure, the capillary component 8 of the capillary structure close to the reservoir 5 is provided with a concave structure at the communication position between the evaporator 1 and the auxiliary line 6, the concave structure extends along a length direction of the capillary component 8 to form a straight groove, the length direction of the capillary component 8 is defined as a direction perpendicular to a direction in which the evaporator 1 transfers heat to the reservoir 5, and the second vapor chamber 7 is formed between the straight groove and the housing 11. In the component of the fourth example, the capillary component 8 can be part of the capillary wick 12, and the formed capillary structure thus has a one-piece structure. The capillary wick 12 and the capillary component 8 can also be separate structures that are in contact or connected with each other, the formed capillary structure thus has a separable structure.

FIGS. 6 and 7 show the fifth example of the component for reducing the heat transfer temperature difference of the loop heat pipe of Embodiment II. The component of the fifth example is similar to that of the first example, so the similarities will not be repeated. The differences are that, in the component of the fifth example, a first channel 71 and a plurality of second channels 72 are provided on the capillary component 8 of the capillary structure close to the reservoir 5, the first channel 71 is provided at the communication position between the evaporator 1 and the auxiliary line 6, a plurality of second channels 72 is distributed on the capillary structure, and each of the second channels communicates with the first channel 71. Each of the second channels 72 extends along a circumferential direction of an outer peripheral surface of the capillary component 8 to form an annular channel, the second channels 72 are evenly spaced at an interval from each other along an axial direction of the capillary component 8 in the outer peripheral surface of the capillary component 8, and the first channel 71 extends along the axial direction of the capillary component 8 in the outer peripheral surface of the capillary component 8 to communicate with each of the second channels 72. The first channel 71 and the plurality of second channels 72 together form the second vapor chamber 7 with the housing 11, and the auxiliary line 6 communicates with the first channel 71.

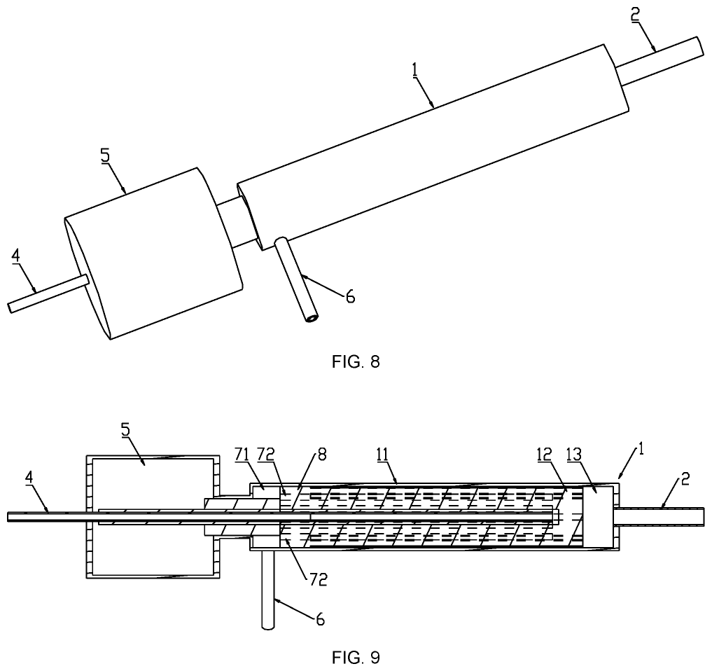

FIGS. 8 and 9 show the sixth example of the component for reducing the heat transfer temperature difference of the loop heat pipe of Embodiment II. The component of the sixth example is similar to that of the first example, so the similarities will not be repeated. The differences are that, in the component of the sixth example, the first channel 71 and the plurality of second channels 72 are provided on the capillary component 8 of the capillary structure close to the reservoir 5, the first channel 71 is provided at the communication position between the evaporator 1 and the auxiliary line 6, the plurality of second channels 72 is distributed on the capillary structure, and each of the second channels communicates with the first channel 71. Each of the second channels 72 is an axial slot providing in the capillary component 8 and extending along the axial direction thereof. The second channels 72 are evenly spaced at an interval from each other along the circumferential direction of the capillary component 8, and the first channel 71 extends along the circumferential direction of the capillary component 8 in the outer peripheral surface of the capillary component 8 to form the annular channel and to communicate with each of the second channels 72. The first channel 71 and the plurality of second channels 72 together form the second vapor chamber 7 with the housing 11, and the auxiliary line 6 communicates with the first channel 71.

According to the component for reducing the heat transfer temperature difference of the loop heat pipe of Embodiment II, the limitation of the principle of the loop heat pipe used in aerospace is broken, and the heat leakage can be reduced without limiting materials and working medium, so that more favorable materials, working medium and matched processes can be adopted to meet the requirements of civilian devices with high power and high heat-flux density. The heat transfer temperature difference generated by conventional loop heat pipes using the same working medium and an approximate capillary structure generally exceeds 35° C., while the heat transfer temperature difference generated by the component of Embodiment II can be reduced to 5-10° C. or less, therefore, the performance of the improved loop heat pipe can meet the requirements of civilian devices such as chips and power electronic devices.

### Embodiment III

Refer to FIGS. 10 to 13, a loop heat pipe is provided according to Embodiment III of the present disclosure, based on the component for reducing the heat transfer temperature difference of the loop heat pipe of Embodiment II. The loop heat pipe of Embodiment III includes the component for reducing the heat transfer temperature difference of the loop heat pipe of Embodiment II.

Further, the loop heat pipe of Embodiment III also includes a vapor line 2, a condenser 3, a liquid line 4, and auxiliary line 6. The vapor line 2 connects a first vapor chamber 13 with an inlet of the condenser 3, and the liquid line 4 connects a reservoir 5 with an outlet of the condenser 3. The second vapor chamber 7 and the liquid line 4 communicate with each other by the auxiliary line 6.

The working principle of the loop heat pipe of Embodiment III is as follows: when an evaporator 1 is in contact with a heat source to absorb heat from the heat source, the working medium in the first vapor chamber 13 is vaporized, and the vaporized working medium passes through the vapor line 2 and enters the condenser 3, the vaporized working medium exothermically condenses into the liquid-phase working medium in the condenser 3, then the liquid-phase working medium passes through the liquid line 4 and flows back to the reservoir 5 and the evaporator 1, thus completing one cycle. At the same time, as the temperature and pressure of the evaporator 1 are higher than those of the working medium in reservoir 5, the evaporator 1 begins to transfer heat to the reservoir 5. When the heat is transferred to the second vapor chamber 7, the liquid-phase working medium in the second vapor chamber 7 is heated and vaporized, this process absorbs most of the heat transferred from the evaporator 1 to the reservoir 5, thus significantly reducing the heat leaked to the reservoir 5. The working medium vaporized in the second vapor chamber 7 passes through the auxiliary line 6 and flows to the liquid line 4, then flows back to the reservoir 5 together with the condensed working medium that flows through the vapor line 2, thereby completing another cycle. These two cycles are performed side-by-side at the same time.

Therefore, in the loop heat pipe of Embodiment III, by adding the second vapor chamber 7 and the auxiliary line 6, the heat leakage from the evaporator 1 to the reservoir 5 is isolated by the second vapor chamber 7. Specifically, part of the working medium is vaporized in the second vapor chamber 7 due to the heat leakage, the vaporized working medium in the second vapor chamber 7 flows to the auxiliary line 6, and finally flows back to the reservoir 5 to complete a cycle. The vaporization of the working medium in the second vapor chamber 7 absorbs most of the heat leakage from the evaporator 1 to the reservoir 5, which can significantly reduce the heat leaked to the reservoir 5, thereby effectively reducing the heat transfer temperature difference of the loop heat pipe, and ensuring that the advantageous performance of the loop heat pipe can be well applied to civilian devices.

In the loop heat pipe of Embodiment III, the communication method between the auxiliary line 6 and the liquid line 4 is not limited, and any one of the following three communication methods can be preferably adopted.

Refer to FIG. 10, in the first preferred communication method between the auxiliary line 6 and the liquid line 4, a working medium channel 31 that communicates with the liquid line 4 is provided inside the condenser 3, two ends of the auxiliary line 6 respectively communicate with the second vapor chamber 7 and the working medium channel 31, and the auxiliary line 6 communicates with the liquid line 4 through the working medium channel 31 and the outlet of the condenser 3, thus the second vapor chamber 7 can communicate with the liquid line 4 via the auxiliary line 6. Therefore, the vaporized working medium in the second vapor chamber 7 enters the auxiliary line 6, then passes through the auxiliary line 6 and the working medium channel 31, and flows to the condenser 3. The vaporized working medium exothermically condenses into the liquid-phase working medium in the condenser 3, and the liquid-phase working medium then passes through the liquid line 4 and flows back to the reservoir 5 together with the condensed working medium that flows through the vapor line 2.

Refer to FIG. 11, in the second preferred communication method between the auxiliary line 6 and the liquid line 4, an auxiliary condenser 9 is provided on the auxiliary line 6, and the two ends of the auxiliary line 6 communicate with the second vapor chamber 7 and the liquid line 4 respectively. Thus, the vaporized working medium in the second vapor chamber 7 flows through the auxiliary line 6, and enters the auxiliary condenser 9. The vaporized working medium condenses into the liquid-phase working medium in the auxiliary condenser 9, and the liquid-phase working medium then passes through the liquid line 4 and flows back to the reservoir 5.

Refer to FIGS. 12 and 13, in the third preferred communication method between the auxiliary line 6 and the liquid line 4, the auxiliary line 6 can pass through the condenser 3, the two ends of the auxiliary line 6 communicate with the second vapor chamber 7 and the liquid line 4 respectively, and part of the auxiliary line 6 passes through the condenser 3. Thus, the vaporized working medium in the second vapor chamber 7 flows through the auxiliary line 6, and enters the condenser 3. The vaporized working medium condenses into the liquid-phase working medium in the condenser 3, and the liquid-phase working medium then passes through the liquid line 4 and flows back to the reservoir 5.

Four specific examples of the loop heat pipe of Embodiment III are provided below.

FIG. 10 shows the first example of the loop heat pipe of Embodiment III. The loop heat pipe of the first example adopts the structure of the component for reducing the heat transfer temperature difference of the loop heat pipe of the first example in Embodiment II. The vapor line 2 connects the first vapor chamber 13 and the inlet of the condenser 3, and the liquid line 4 connects the reservoir 5 with the outlet of the condenser 3. The second vapor chamber 7 and the liquid line 4 communicate with each other by the auxiliary line 6, and the auxiliary line 6 communicates with the liquid line 4 through the working medium channel 31, which communicates with the liquid line 4 and is provided in the condenser 3. The second vapor chamber 7 and the working medium channel 31 communicate with each other by the auxiliary line 6. The structure of any other examples of the component for reducing the heat transfer temperature difference of the loop heat pipe in Embodiment II may also be adopted in the loop heat pipe of the first example in Embodiment III.

FIG. 11 shows the second example of the loop heat pipe of Embodiment III. The loop heat pipe of the second example is similar to that of the first example, so the similarities will not be repeated. The difference is that, in the loop heat pipe of the second example, the auxiliary line 6 communicates with the liquid line 4 through the auxiliary condenser 9 provided on the auxiliary line 6.

FIG. 12 shows the third example of the loop heat pipe of Embodiment III. The loop heat pipe of the third example is similar to that of the first example, so the similarities will not be repeated. The difference is that, in the loop heat pipe of the third example, the auxiliary line 6 communicates with the liquid line 4 by passing through the condenser 3.

FIG. 13 shows the fourth example of the loop heat pipe of Embodiment III. The loop heat pipe of the fourth example is similar to that of the third example, so the similarities will not be repeated. The difference is that the loop heat pipe of the fourth example adopts the structure of the component for reducing the heat transfer temperature difference of the loop heat pipe of the fourth example in Embodiment II.

According to the loop heat pipe of Embodiment III, the limitation of the principle of the loop heat pipe used in aerospace is broken, and the heat leakage can be reduced without limiting materials and working medium, so that more favorable materials, working medium and matched processes can be adopted to meet the requirements of civilian devices with high power and high heat-flux density. The heat transfer temperature difference generated by conventional loop heat pipes using the same working medium and an approximate capillary structure generally exceeds 35° C., while the heat transfer temperature difference generated by the loop heat pipe of Embodiment III can be reduced to 5-10° C. or less, so that the performance of the improved loop heat pipe can meet the requirements of civilian devices such as chips and power electronic devices.

The above description is only preferred embodiments of the present disclosure, and it should be noted that for those of ordinary skill in the art, various improvements and replacements can be made without departing from the technical principle of the present disclosure, these improvements and replacements should also be considered as the protection scope of the present disclosure.

1. A method for reducing a heat transfer temperature difference of a loop heat pipe, comprising:
providing a second vapor chamber (7) between a first vapor chamber (13) of an evaporator (1) and a reservoir (5), and
separating the first vapor chamber (13) from the second vapor chamber (7) and separating the second vapor chamber (7) from the reservoir (5) by a capillary structure,
wherein the first vapor chamber (13) communicates with a vapor line (2), and the second vapor chamber (7) communicates with a liquid line (4) through an auxiliary line (6).

2. The method for reducing the heat transfer temperature difference of the loop heat pipe according to claim 1, further comprising:
providing a working medium channel (31) that communicates with the liquid line (4) in a condenser (3), wherein the second vapor chamber (7) and the working medium channel (31) communicate with each other by the auxiliary line (6).

3. The method for reducing the heat transfer temperature difference of the loop heat pipe according to claim 1, further comprising:
providing an auxiliary condenser (9) on the auxiliary line (6).

4. The method for reducing the heat transfer temperature difference of the loop heat pipe according to claim 1, further comprising:
setting the auxiliary line (6) to pass through the condenser (3).

5. A component for reducing a heat transfer temperature difference of a loop heat pipe, comprising an evaporator (1) and a reservoir (5), wherein the evaporator (1) includes a housing (11) and a capillary structure, wherein a first vapor chamber (13) that communicates with a vapor line (2) and a second vapor chamber (7) that communicates with an auxiliary line (6) are formed between the capillary structure and the housing (11), wherein the auxiliary line (6) is configured to communicate with a liquid line (4), the second vapor chamber (7) is provided between the first vapor chamber (13) and the reservoir (5), and the capillary structure is configured to separate the first vapor chamber (13) from the second vapor chamber (7) and to separate the second vapor chamber (7) from the reservoir (5).

6. The component for reducing the heat transfer temperature difference of the loop heat pipe according to claim 5, wherein the capillary structure is a one-piece structure.

7. The component for reducing the heat transfer temperature difference of the loop heat pipe according to claim 5, wherein the capillary structure is a separable structure, and the capillary structure includes a capillary wick (12) and a capillary component (8), wherein the first vapor chamber (13) is formed between the capillary wick (12) and the housing (11), the second vapor chamber (7) is formed between the capillary component (8) and the housing (11), and the capillary wick (12) is in contact with or connected to the capillary component (8).

8. The component for reducing the heat transfer temperature difference of the loop heat pipe according to claim 5, wherein the capillary structure is provided with a concave structure at a communication position between the evaporator (1) and the auxiliary line (6), and the second vapor chamber (7) is formed between the concave structure and the housing (11).

9. The component for reducing the heat transfer temperature difference of the loop heat pipe according to claim 5, wherein a first channel (71) and a plurality of second channels (72) are provided in the capillary structure, wherein the first channel (71) is provided at a communication position between the evaporator (1) and the auxiliary line (6), the plurality of second channels (72) is distributed on the capillary structure, each of the plurality of second channels is communicated with the first channel (71), and the first channel (71) and the plurality of second channels (72) together form the second vapor chamber (7) with the housing (11).

10. The component for reducing the heat transfer temperature difference of the loop heat pipe according to claim 5, wherein the housing (11) is provided with a convex structure at a communication position between the evaporator (1) and the auxiliary line (6), and the second vapor chamber (7) is formed between the convex structure and the capillary structure.

11. The component for reducing the heat transfer temperature difference of the loop heat pipe according to claim 5, wherein a wall of the housing (11) is thinned to form a groove on a surface of the wall at a communication position between the evaporator (1) and the auxiliary line (6), and the second vapor chamber (7) is formed between the groove and the capillary structure.

12. The component for reducing the heat transfer temperature difference of the loop heat pipe according to claim 5, wherein a porous structure is provided in the second vapor chamber (7).

13. A loop heat pipe, comprising the component for reducing the heat transfer temperature difference of the loop heat pipe according to claim 5.

14. The loop heat pipe according to claim 13, further comprising the vapor line (2), a condenser (3), the liquid line (4) and the auxiliary line (6), wherein the vapor line (2) connects the first vapor chamber (13) with an inlet of the condenser (3), the liquid line (4) connects the reservoir (5) with an outlet of the condenser (3), and the second vapor chamber (7) and the liquid line (4) communicate with each other by the auxiliary line (6).

15. The loop heat pipe according to claim 14, wherein a working medium channel (31) that communicates with the liquid line (4) is provided inside the condenser (3), and the second vapor chamber (7) and the working medium channel (31) communicate with each other by the auxiliary line (6).

16. The loop heat pipe according to claim 14, wherein an auxiliary condenser (9) is provided on the auxiliary line (6).

17. The loop heat pipe according to claim 14, wherein the auxiliary line (6) passes through the condenser (3).
